(19) United States
(12) Patent Application Publication
(10) Pub. No.: US 2008/0002750 A1
(43) Pub. Date: Jan. 3, 2008

(54) Surface emitting semiconductor device

(75) Inventors: Yutaka Onishi, Yokohama-shi (JP); Hideyuki Doi, Yokohama-shi (JP)

Correspondence Address: SMITH, GAMBRELL & RUSSELL, 1130 CONNECTICUT AVENUE, N.W., SUITE 1130, WASHINGTON, DC, 20036, US

(73) Assignee: SUMITOMO ELECTRIC INDUSTRIES, LTD.

(21) Appl. No.: 11/819,246

(22) Filed: Jun. 26, 2007

(30) Foreign Application Priority Data
Jun. 29, 2006 (JP) P2006-179793

(51) Int. Cl. H01S 5/026; H01L 33/00

(52) U.S. Cl. 372/50.11; 257/98; 257/E33.026; 257/E33.069

(57) ABSTRACT

A surface emitting semiconductor device comprises an active layer, a p-type III-V compound semiconductor layer, an n-type III-V compound semiconductor layer, and a burying layer. The active layer includes a primary surface, the primary surface having first and second areas. The p-type III-V compound semiconductor layer is provided on the first and second areas of the primary surface of the active layer. The n-type III-V compound semiconductor layer is provided on the second area of the primary surface of the active layer. The n-type III-V compound semiconductor is provided on the p-type III-V compound semiconductor layer. The n-type III-V compound semiconductor and the p-type III-V compound semiconductor layer form a tunnel junction. The n-type III-V compound semiconductor layer contains tellurium as an n-type dopant. The burying layer is made of III-V compound semiconductor. The n-type III-V compound semiconductor layer is covered with the burying layer.

### BACKGROUND OF THE INVENTION

1. Field of the Invention

The present invention relates to a surface emitting semiconductor device.

2. Related Background Art

Publication 1 (N. Nishiyama et al., Electronics Letters, vol. 39, No. 5, pp. 437-439, 2003) discloses a vertical cavity surface emitting laser (VCSEL) having a tunnel junction. This tunnel junction is formed by an n-type semiconductor layer and a p-type semiconductor layer.

### SUMMARY OF THE INVENTION

Silicon is generally used as an n-type dopant for an n-type semiconductor for the tunnel junction. The Si-doped n-type semiconductor layer cannot be provided with a sufficiently high carrier concentration, and the contact resistance of the tunnel junction becomes high. Consequently, the differential resistance of the surface emitting device cannot be lowered.

Since a depletion layer becomes thick in the n-type semiconductor layer of a low carrier concentration, it is necessary to increase the thickness of the n-type semiconductor layer. The surface flatness of the burying layer is degraded due to the anomalous growth of the burying layer which covers the n-type semiconductor layer. When light from the active layer passes through the burying layer, the light is scattered or diffracted at the surface flatness of the burying layer. The optical output of the surface emitting semiconductor device cannot be improved because of optical loss through the scattering and diffraction.

It is an object to provide a surface emitting semiconductor device having a small differential resistance and a large optical output.

A surface emitting semiconductor device according to the present invention comprises an active layer, a p-type III-V compound semiconductor layer, an n-type III-V compound semiconductor layer, and a burying layer. The active layer includes a primary surface having first and second areas. The p-type III-V compound semiconductor layer is provided on the first and second areas of the primary surface of the active layer. The n-type III-V compound semiconductor layer is provided on the second area of the primary surface of the active layer. The n-type III-V compound semiconductor is provided on the p-type III-V compound semiconductor layer. The n-type III-V compound semiconductor and the p-type III-V compound semiconductor layer form a tunnel junction. The n-type III-V compound semiconductor layer containing tellurium as an n-type dopant. The burying layer is made of III-V compound semiconductor. The n-type III-V compound semiconductor layer is buried by the burying layer.

In the surface emitting semiconductor device according to the present invention, the p-type III-V compound semiconductor layer contains carbon as a p-type dopant. Further, in the surface emitting semiconductor device according to the present invention, the thickness of the n-type III-V compound semiconductor layer is equal to or less than 50 nanometers. Furthermore, in the surface emitting semiconductor device according to the present invention, the n-type III-V compound semiconductor layer includes In_{X}Ga_{1-X}As (0.05≦x≦0.4).

In the surface emitting semiconductor device according to the present invention, the n-type III-V compound semiconductor layer and the p-type III-V compound semiconductor layer form a type II superlattice structure. Alternatively, in the surface emitting semiconductor device according to the present invention, the n-type III-V compound semiconductor layer and the p-type III-V compound semiconductor layer form a type I superlattice structure. In these surface emitting semiconductor device, the n-type III-V compound semiconductor layer has a top and a side, and the burying layer covers the top and the side of the n-type III-V compound semiconductor layer.

In the surface emitting semiconductor device according to the present invention, the p-type III-V compound semiconductor layer is made of InGaAs, and the n-type III-V compound semiconductor layer is made of one of the following: InGaAs; GaAsSb; GaInNAs; and GaInNAsSb.

The surface emitting semiconductor device according to the present invention further comprises an n-type semiconductor substrate, a first distributed Bragg reflector, and a second distributed Bragg reflector. The p-type III-V compound semiconductor layer, the active layer and the n-type III-V compound semiconductor layer are arranged between the first distributed Bragg reflector and the second distributed Bragg reflector. The first and second distributed Bragg reflectors are mounted on the n-type semiconductor substrate.

The surface emitting semiconductor device according to the present invention further comprises a contact layer provided on the burying layer, and the contact layer is doped with an n-type dopant.

In the surface emitting semiconductor device according to the present invention, the burying layer is doped with an n-type dopant. Further, in the surface emitting semiconductor device according to the present invention, the n-type dopant in the burying layer is different form the n-type dopant in the contact layer. Furthermore, in the surface emitting semiconductor device according to the present invention, the n-type dopant in the burying layer is Si and the n-type dopant in the contact layer is Te.

The surface emitting semiconductor device according to the present invention further comprises a first distributed Bragg reflector and a second distributed Bragg reflector. The p-type III-V compound semiconductor layer, the active layer and the n-type III-V compound semiconductor layer are provided between the first distributed Bragg reflector and second distributed Bragg reflector.

The surface emitting semiconductor device according to the present invention further comprises a contact layer, a first distributed Bragg reflector, and a second distributed Bragg reflector. The contact layer is provided on the burying layer. The second distributed Bragg reflector is provided on the contact layer. The p-type III-V compound semiconductor layer, the active layer, the n-type III-V compound semiconductor layer and the contact layer are arranged between the first distributed Bragg reflector and the second distributed Bragg reflector.

In the surface emitting semiconductor device according to the present invention, the n-type III-V compound semiconductor layer has a mesa. The first distributed Bragg reflector, the n-type III-V compound semiconductor layer, the active layer and the second distributed Bragg reflector are arranged on a predetermined axis. Further, in the surface emitting semiconductor device according to the present invention, the second distributed Bragg reflector includes first III-V compound semiconductor layers and second III-V compound semiconductor layers, and the first III-V compound semiconductor layers and second III-V compound semiconductor layers are arranged alternately. Furthermore, in the surface emitting semiconductor device according to the present invention, the second distributed Bragg reflector includes first dielectric layers and second dielectric layers, and the dielectric layers and second dielectric layers are arranged alternately.

In the surface emitting semiconductor device according to the present invention, the surface emitting semiconductor device includes a surface emitting semiconductor laser.

### BRIEF DESCRIPTION OF THE DRAWINGS

The above object and other objects, features, and advantages of the present invention will be understood easily from the following detailed description of the preferred embodiments of the present invention with reference to the accompanying drawings.

FIG. 1 is a schematic cross sectional view showing the structure of a surface emitting semiconductor device according to the present embodiment;

FIG. 2 is a cross sectional view showing the fabrication steps for the surface emitting semiconductor device;

FIG. 3 is a graph showing the relationship between the electron concentration of a GaAs layer doped with Te and the growth temperature of the GaAs layer;

FIG. 4 is a graph showing the relationship between the electron concentration of an InGaAs layer doped with Te and the growth temperature of the InGaAs layer;

FIG. 5 is a graph showing the relationship between the etch pit density (EPD) of the surface of an InGaAs layer doped with Te and the thickness “d” of the InGaAs layer;

FIG. 6 is a graph showing the relationship between the electron concentration and EPD of an In_{X}Ga_{1-X}As layer doped with Te and the composition “X” of the In_{X}Ga_{1-X}As layer;

FIG. 7 is a graph showing current versus optical output characteristics of the surface emitting lasers of Embodiment 1 and Comparative Example 1; and

FIG. 8 is a graph showing current versus voltage characteristics of the surface emitting lasers of Embodiment 1.

### DETAILED DESCRIPTION OF THE PREFERRED EMBODIMENTS

Referring to the accompanying drawings, embodiments of the present invention will be explained. When possible, parts identical to each other will be referred to with symbols identical to each other.

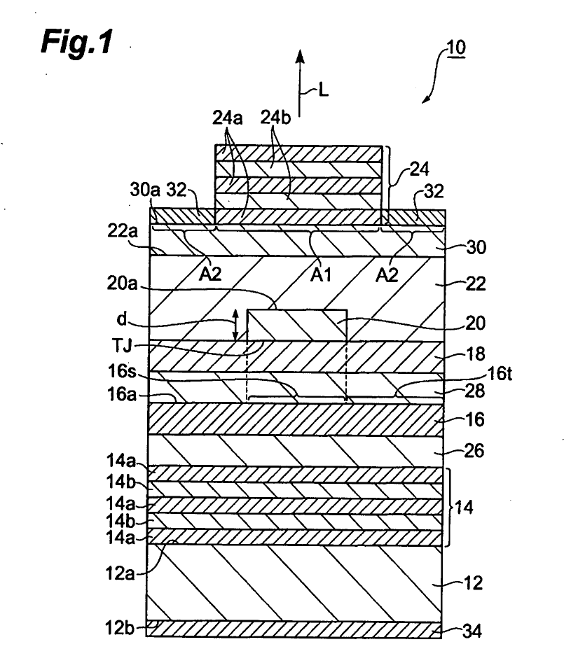

FIG. 1 is a schematic cross sectional view showing the structure of a surface emitting semiconductor device according to the present embodiment. One example of a surface emitting laser 10 (surface emitting semiconductor device) shown in FIG. 1 is a VCSEL. The surface emitting laser 10 comprises a p-type III-V compound semiconductor layer 18 provided on an active layer 16, an n-type III-V compound semiconductor layer 20 provided on the p-type III-V compound semiconductor layer 18, and an n-type burying layer 22 burying the n-type III-V compound semiconductor layer 20. The burying layer 22 is made of n-type III-V compound semiconductor. The n-type III-V compound semiconductor layer 20 is provided on first area 16s of a primary surface 16a of the active layer 16. The n-type III-V compound semiconductor layer 18 is provided on the first and second areas 16s, 16t of the primary surface 16a. The second area 16t surrounds the first area 16s. In one example, the shape of the first area 16s is a circle, the diameter of which is five micrometers. The n-type III-V compound semiconductor layer 20 has a mesa shape, for example. The top and side of the mesa is covered with the burying layer 22.

The n-type III-V compound semiconductor 20 and p-type III-V compound semiconductor layer 18 form a tunnel junction TJ. It is preferable that the n-type II-V compound semiconductor 20 and p-type III-V compound semiconductor layer 18 form a type II superlattice structure. In the type II superlattice, the valence band energy level of the p-type III-V compound semiconductor layer 18 is higher than that of the n-type III-V compound semiconductor 20. When the n-type III-V compound semiconductor 20 and p-type III-v compound semiconductor layer 18 form a type I superlattice structure, the valence band energy level of the p-type III-V compound semiconductor layer 18 is lower than that of the n-type III-V compound semiconductor 20.

Since the valence band energy difference between the p-type III-V compound semiconductor layer 18 and the n-type III-V compound semiconductor 20 in the type II superlattice structure is made smaller as compared to type I superlattice structures, the tunneling probability in the tunnel junction TJ of the type II superlattice is increased, thereby facilitating the generation of tunneling current. For example, when the p-type III-V compound semiconductor layer 18 is made of GaAsSb and the n-type III-V compound semiconductor 20 is made of InGaAs, these layers form a type II superlattice structure.

The active layer 16, the p-type III-V compound semiconductor layer 18, the n-type III-V compound semiconductor 20 and the burying layer 22 are arranged between a distributed Bragg reflector (DBR) portion 14 and a DBR portion 24 that are provided for the optical cavity. The active layer 16 is located on the DBR portion 14 and the DBR portion 24 is located on the burying layer 22.

The DBR portion 14 includes III-V compound semiconductor layers 14a and III-V compound semiconductor layers 14b that alternately arranged. The III-V compound semiconductor layers 14a are made of, for example, an n-type GaAs doped with Si and the III-V compound semiconductor layers 14b are made of, for example, Al_{0.9}Ga_{0.1}As. The DBR portion 24 includes amorphous silicon layers 24a and aluminum oxide layers 24b that alternately arranged. The DBR portion 24 may include III-V compound semiconductor layers that alternately arranged, and include dielectric layers that alternately arranged. The heat radiation performance in the light emitting semiconductor device of the DBR portion 24 including III-V compound semiconductor layers is improved as compared to that of a DBR portion including dielectric layers. In one example, the DBR portion 24 includes GaAs layers and AlGaAs layers that alternately arranged.

The DBR portion 14 is provided on the surface 12a of a substrate 12. The substrate 12 is, for example, a GaAs substrate, or may be an InP substrate. A spacer layer 26 is provided between the DBR portion 14 and the active layer 16. The spacer layer 26 is made of, for example, an n-type GaAs. Another spacer layer 28 is provided between the active layer 16 and the p-type III-V compound semiconductor layer 18. The spacer layer 28 is made of, for example, a p-type GaAs. The contact layer 30 is provided between the DBR portion 24 and the burying layer 22. The DBR portion 24 is provided on the first area A1 of the primary surface 30a of the contact layer 30. The first area A1 is located on the first area 16s. An electrode 32 is provided on the second area A2 of the primary surface 30a which surrounds the first area A1. The electrode 32 is made of, for example, Ti/Pt/Au. This surface emitting laser has a long term stability. An electrode 34 is provided on the back side 12b of the substrate 12. The electrode 34 is made of, for example, Au/AuGe/Ni.

It is preferable that the active layer 16 have a quantum well structure and it is more preferable that the active layer 16 have a multiple quantum well structure. The active layer 16 includes, for example, InGaAs.

The p-type III-V compound semiconductor layer 18 includes, for example, InGaAs. It is preferable that the p-type III-V compound semiconductor layer 18 contain, for example, carbon as a p-type dopant. The diffusion coefficient of carbon is smaller than that of other p-type dopants. The carbon dopant can prevent the p-type dopant diffusion to the active layer and the change of the band structure in the tunnel junction due to the p-type dopant diffusion. The carrier concentration in the p-type III-V compound semiconductor layer containing carbon is increased as compared to p-type III-V compound semiconductor layers containing other p-type dopants.

The n-type III-V compound semiconductor layer 20 contains tellurium (Te) as an n-type dopant. It is preferable that the n-type III-V compound semiconductor layer 20 include In_{X}Ga_{1-X}As (0≦X≦1), and the bandgap energy of the n-type III-V compound semiconductor layer 20 is made small. Thus, the differential resistance of the surface emitting laser 10 can be made small. Therefore, the maximum of optical output in the surface emitting laser 10 can be enhanced.

It is preferable that the indium composition of In_{X}Ga_{1-X}As be in the range of 0.05 to 0.4. The n-type III-V compound semiconductor layer 20 having an indium composition in the above range has a smaller bandgap energy than that of the n-type III-V compound semiconductor layer 20 of GaAs, and thus the contact resistance of the tunnel junction TJ can be made smaller. If the indium composition “X” of the n-type III-V compound semiconductor layer 20 is equal to or less than 0.4, the etch pit density in the surface 20a is made much smaller than that of an n-type III-V compound semiconductor layer having an indium composition of more than 0.4.

The n-type III-V compound semiconductor layer 20 may contain constituents of at least one of In, N, and Sb in addition to Ga and As. The bandgap of this n-type III-V compound semiconductor layer 20 can be made smaller. The n-type III-V compound semiconductor layer 20 may be made of, for example, GaAsSb, InGaAs, GaInNAs, and GaInNAsSb.

It is preferable that the thickness “d” of the n-type III-V compound semiconductor layer 20 be equal to or less than 50 nanometers. The etch pit density in the surface 20a of the n-type III-V compound semiconductor layer 20 having a thickness of equal to or less than 50 nanometers can be made smaller than that of a thickness of more than 50 nanometers. Therefore, the flatness of the surface 20a of the n-type III-V compound semiconductor layer 20 is improved. Consequently, when light from the active layer 16 passes through the n-type III-V compound semiconductor layer 20, the flat surface 20a of the n-type III-V compound semiconductor layer 20 can prevent the scattering and/or diffraction of the light. Therefore, the optical loss can be reduced and thus the optical output of the surface emitting semiconductor device 10 can be improved. It is preferable that the thickness “d” of the n-type III-V compound semiconductor layer 20 be made small because the free electron absorption in the n-type III-V compound semiconductor layer 20 can be reduced. In one example, the thickness “d” of the n-type III-V compound semiconductor layer 20 is 10 nanometers.

Preferably, the dopant concentration (tellurium concentration) of the n-type III-V compound semiconductor layer 20 is equal to or more than 1×10¹⁸ cm⁻³, and more preferably 1×10¹⁹ cm⁻³.

It is preferable that impurity levels from oxygen be introduced around the interface between the p-type III-V compound semiconductor layer 18 and the n-type III-V compound semiconductor 20. The tunnel transition therebetween is facilitated through the impurity levels, and thus the contact resistance in the tunnel junction is lowered.

The burying layer 22 is, for example, an n-type GaAs layer doped with Si. The contact layer 30 is, for example, an n-type GaAs layer doped with Te.

In the surface emitting laser 10 according to the present embodiment, since the n-type III-V compound semiconductor 20 is doped with Te of an n-type dopant, the carrier concentration (electron concentration) of the n-type III-V compound semiconductor 20 can be increased. The activation rate of Te dopant is higher than that of another n-type dopant, such as Si and the like. Accordingly, since the contact resistance of the tunnel junction TJ is reduced, the differential resistance is made smaller, thereby preventing the saturation of optical output due to heat generated in the surface emitting laser 10. Therefore, the maximum optical output of the surface emitting laser 10 is improved.

Since the thickness of the depletion layer is made small by increasing the carrier concentration of the n-type III-V compound semiconductor 20, the n-type III-V compound semiconductor 20 can be made thin, thereby improving the flatness of surface 22a of the burying layer 22. Consequently, when light from the active layer 16 passes through the burying layer 22, the flat surface 22a of the burying layer 22 can prevent the scattering and/or diffraction of the light. Therefore, the optical loss can be decreased and thus the optical output of the surface emitting laser 10 can be improved. When the surface 22a is flattened, the flatness of the DBR portion 24 is also made excellent, thereby improving the reflection characteristics.

The strain of the n-type III-V compound semiconductor 20 is reduced by thinning the n-type III-V compound semiconductor 20 in thickness. Accordingly, one or more constituents (for example, In atom and Sb atom) that increase strain and decrease a bandgap energy can be heavily introduced into the n-type III-V compound semiconductor 20. Therefore, the stain of the n-type III-V compound semiconductor 20 can be reduced and the bandgap of the n-type III-V compound semiconductor 20 can be also made smaller.

Since the diffusion coefficient of tellurium is smaller than that of other n-type dopants, such as Si, the diffusion of tellurium hardly occurs in the surface emitting laser 10 operated under the application of high current. Thus, the aging degradation of the tunnel junction TJ due to the dopant diffusion hardly occurs. Therefore, since the optical output of the surface emitting laser 10 is stabilized for the long term, the surface emitting laser 10 has a high reliability.

As explained above, in the present embodiment, the differential resistance of the surface emitting laser 10 becomes low and its optical output becomes large.

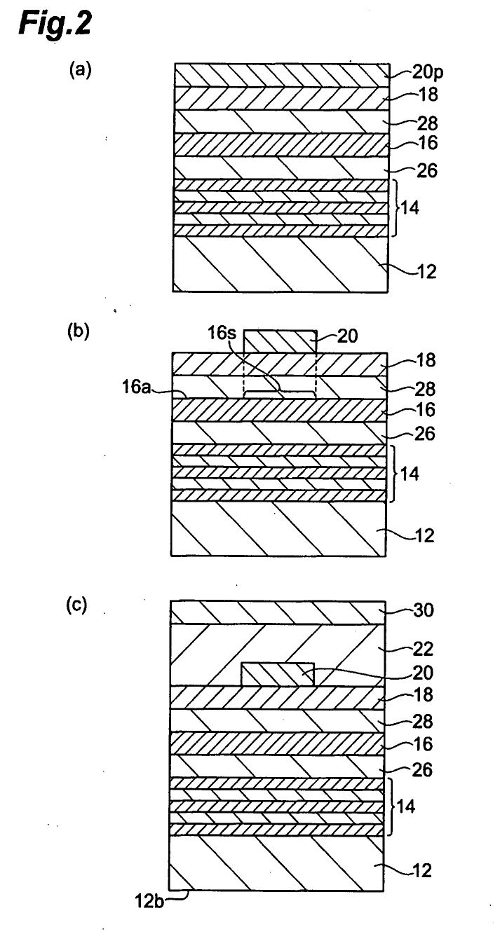

FIG. 2 is a cross sectional view showing the fabrication steps for the surface emitting semiconductor device. One example of the fabrication of the surface emitting laser 10 will be explained below.

(Growth Step)

As shown in Part (a) of FIG. 2, the DBR portion 14, spacer layer 26, active layer 16, spacer layer 28, p-type III-V compound semiconductor layer 18 and n-type III-V compound semiconductor layer 20p are sequentially formed on the substrate 12. If not required, the spacer layers 26, 28 may not be formed. The n-type III-V compound semiconductor layer 20p is used for forming an n-type III-V compound semiconductor layer 20. The DBR portion 14, spacer layer 26, active layer 16, spacer layer 28, p-type III-V compound semiconductor layer 18 and n-type III-V compound semiconductor layer 20p are grown by vapor phase epitaxy method, such as MOVPE method and MBE method. In order to form the n-type III-V compound semiconductor layer 20p, gas containing tellurium as its constituent, such as diethyl-tellurium, can be used as a precursor.

In the n-type III-V compound semiconductor layer 20p doped with tellurium of an n-type dopant, when the growth temperature of the n-type III-V compound semiconductor layer 20p is made low, the dopant concentration of the n-type III-V compound semiconductor layer 20p can be increased. When the p-type III-V compound semiconductor layer 18 contains carbon as a p-type dopant, the growth temperatures of the p-type III-V compound semiconductor layer 18 and n-type III-V compound semiconductor layer 20p are substantially equal to each other. Thus, the p-type III-V compound semiconductor layer 18 and n-type III-V compound semiconductor layer 20p can be successively grown without interruption and this permits the excellent reproducibility of the formation of the tunnel junction TJ.

(Patterning Step)

Next, as Part (b) of shown in FIG. 2, the n-type III-V compound semiconductor layer 20p is etched to form the n-type III-V compound semiconductor layer 20. The n-type III-V compound semiconductor layer 20 can be formed by photolithographic method, for example. Specifically, the n-type III-V compound semiconductor layer 20 can be formed as follows: first, a resist mask is formed on the n-type III-V compound semiconductor layer 20p; next, the photoresist exposure is performed by use of photomask and this exposed photoresist is developed; after wet-etching the n-type III-V compound semiconductor layer 20p by use of the photoresist, this photoresist is removed.

(Regrowth Step)

Next as shown in Part (c) of FIG. 2, a burying layer 22 is regrown on the p-type III-V compound semiconductor layer 18 so as to cover the top and side of the n-type III-V compound semiconductor layer 20. Then, a contact layer 30 is formed on the burying layer 22. The contact layer 30 and burying layer 22 can be grown by vapor phase epitaxy method, such as MOVPE method and MBE method.

(Electrode and DBR Portion Formation Step)

As shown in FIG. 1, an electrode 32 is formed on the contact layer 30, and an electrode 34 is formed on the backside 12b of the substrate 12. Subsequently, a layered product for the DBR portion 24 is formed by evaporation method so as to cover the opening of the electrode 32. Then, the DBR portion 24 is formed by removing a part of the layered product on the electrode 32 by lift-off method.

Although a preferred embodiment according to the present invention has been explained in detail as above, the present invention is not limited thereto.

The present invention will be described below in detail with reference to embodiments and comparative examples, and the present invention is not limited to the following examples.

(Electron Concentration and Growth Temperature Dependence Study)

The relationship between the electron concentration of the n-type III-V compound semiconductor layer 20 and the growth temperature of the n-type III-V compound semiconductor layer 20 was studied as follows:

(1) The n-type III-V compound semiconductor layer 20 is made of GaAs; and

(2) The n-type III-V compound semiconductor layer 20 is made of InGaAs.

(1) GaAs Case

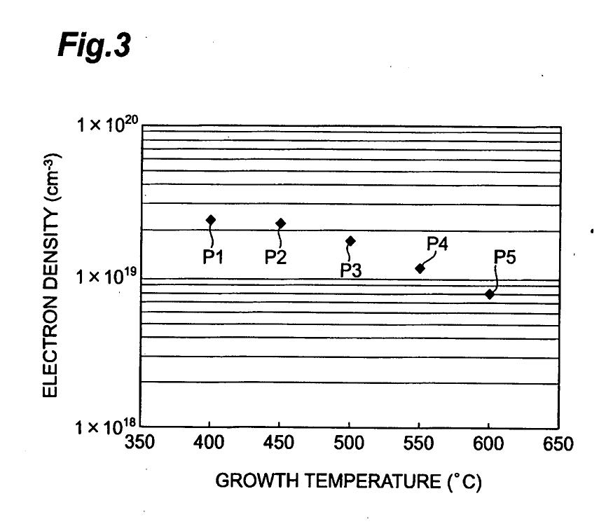

A number of GaAs substrates were prepared and a Te-doped GaAs layer was grown on each GaAs substrate by MOVPE method. Triethyl-gallium (TEGa), diethyl-tellurium (DETe) and arsine (AsH₃) were used as precursors. The growth temperatures of GaAs layers were chosen in the range of 400 to 600 degrees Celsius. The thickness of the GaAs layer on each GaAs substrate was one micrometer. Hole measurement was performed to measure electron concentrations of the above GaAs layers. The measurement results are shown in FIG. 3.

FIG. 3 is a graph showing the relationship between the electron concentration of Te-doped GaAs layers and the growth temperature of the GaAs layers. The graph shows plots P1 to P5: Plot P1 corresponds to the electron concentration of the GaAs layer grown at the growth temperature of 400 degrees Celsius; Plot P2 corresponds to the electron concentration of the GaAs layer grown at the growth temperature of 450 degrees Celsius; Plot P3 corresponds to the electron concentration of the GaAs layer grown at the growth temperature of 500 degrees Celsius; Plot P4 corresponds to the electron concentration of the GaAs layer grown at the growth temperature of 550 degrees Celsius; Plot P5 corresponds to the electron concentration of the GaAs layer grown at the growth temperature of 600 degrees Celsius. The electron concentration P2 is 2.2×10¹⁹ cm⁻³, and the electron concentration P5 is 0.8×10¹⁹ cm⁻³. The graph reveals that the electron concentrations are increased as the growth temperature is lowered.

The surface morphology of the GaAs layer grown at the temperature of 600 degrees Celsius is excellent as compared to the GaAs layer grown at the temperature of 550 degrees Celsius.

(2) InGaAs Case

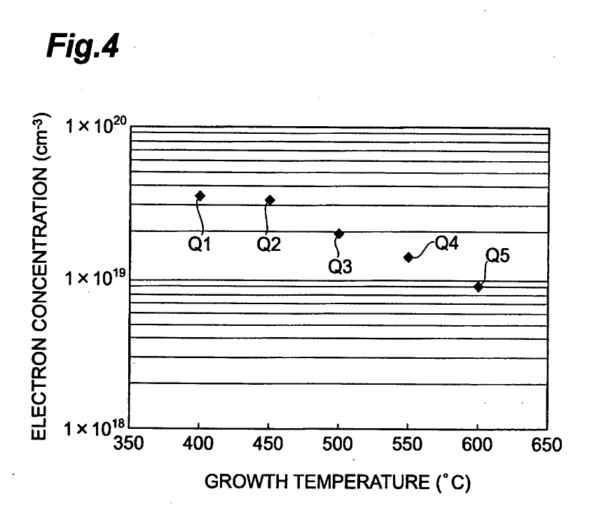

A number of GaAs substrates were prepared and a Te-doped In_{0.1}Ga_{0.9}As layer was grown on each GaAs substrate by MOVPE method. Triethyl-gallium (TEGa), trimethyl-indium (TMIn), diethyl-tellurium (DETe) and arsine (AsH₃) were used as precursors. The growth temperatures of the In_{0.1}Ga_{0.9}As layers were chosen in the range of 400 to 600 degrees Celsius. The thickness of the In_{0.1}Ga_{0.9}As layer on each GaAs substrate was one micrometer. Hole measurements were performed to measure electron concentrations of the above In_{0.1}Ga_{0.9}As layers. The measurement results are shown in FIG. 4.

FIG. 4 is a graph showing the relationship between the electron concentration of Te-doped In_{0.1}Ga_{0.9}As layers and the growth temperature of the In_{0.1}Ga_{0.9}As layers. The graph shows plots Q1 to Q5: Plot Q1 corresponds to the electron concentration of the InGaAs layer grown at the growth temperature of 400 degrees Celsius; Plot Q2 corresponds to the electron concentration of the InGaAs layer grown at the growth temperature of 450 degrees Celsius; Plot Q3 corresponds to the electron concentration of the InGaAs layer grown at the growth temperature of 500 degrees Celsius; Plot Q4 corresponds to the electron concentration of the InGaAs layer grown at the growth temperature of 550 degrees Celsius; Plot Q5 corresponds to the electron concentration of the InGaAs layer grown at the growth temperature of 600 degrees Celsius. The electron concentration Q2 is 3.2×10¹⁹ cm⁻³. Since electron concentrations in Si-doped In_{0.1}Ga_{0.9}As layers is generally 1×10¹⁹ cm⁻³ at most, the doping of the n-type dopant, Te, allows three times the electron concentration of the Si-doped InGaAs layers. The graph reveals that the electron concentration becomes large as the growth temperature is lowered.

The surface morphology of the In_{0.1}Ga_{0.9} As layer grown at the temperature of 600 degrees Celsius is better than that of the In_{0.1}Ga_{0.9}As layer grown at the temperature of 550 degrees Celsius or below.

(Study of Thickness “D” Dependence of Etch Pit Density)

The relationship between the etch pit density (EPD) of the surface 20a of the n-type III-V compound semiconductor layer 20 and the thickness “d” of the n-type III-V compound semiconductor layer 20 was studied. Specifically, the n-type II-V compound semiconductor layer 20 made of an In_{0.1}Ga_{0.9}As layer was studied.

A number of GaAs substrates were prepared and a Te-doped In_{0.1}Ga_{0.9}As layer was grown on each GaAs substrate by MOVPE method. Triethyl-gallium (TEGa), trimethyl-indium (TMIn), diethyl-tellurium (DETe) and arsine (AsH₃) were used as raw material. The growth temperature of the In_{0.1}Ga_{0.9}As layers was 450 degrees Celsius.

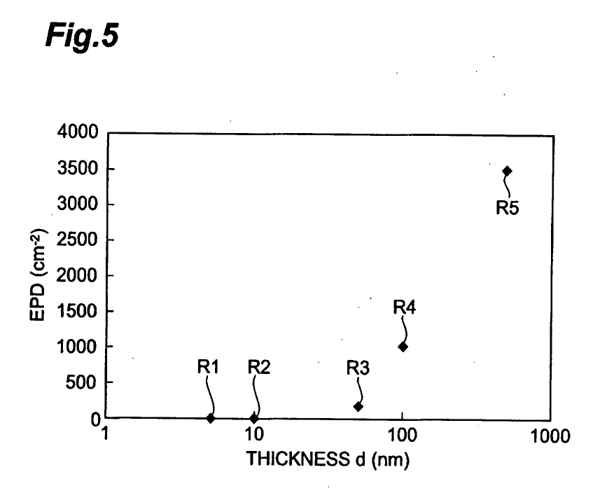

The thickness values of the In_{0.1}Ga_{0.9}As layers were 5 nm, 10 nm, 50 nm, 100 nm and 500 nm. The etch pit density of the surfaces of these In_{0.1}Ga_{0.9}As layers were measured by observing their surfaces. After the In_{0.1}Ga_{0.9}As layers were etched by use of molten KOH, the etch pit density measurements were performed by use of an automated measurement tool. The measurement results are shown in FIG. 5.

FIG. 5 is a graph showing the relationship between the electron concentration of a Te-doped In_{0.1}Ga_{0.9}As layer and the thickness “d” of the In_{0.1}Ga_{0.9}As layer. The graph shows plots R1 to R5: Plot R1 corresponds to the etch pit density of the In_{0.1}Ga_{0.9}As layer having the thickness of 5 nm; Plot R2 corresponds to the etch pit density of the In_{0.1}Ga_{0.9}As layer having the thickness of 10 nm; Plot R3 corresponds to the etch pit density of the In_{0.1}Ga_{0.9}As layer having the thickness of 50 nm; Plot R4 corresponds to the etch pit density of the In_{0.1}Ga_{0.9}As layer having the thickness of 100 nm; Plot R5 corresponds to the etch pit density of the In_{0.1}Ga_{0.9}As layer having the thickness of 500 nm. This graph reveals that the etch pit density of In_{0.1}Ga_{0.9}As layers of the thickness of 50 nm or less is smaller than that of In_{0.1}Ga_{0.9}As layers of the thickness of more than 50 nm. When the thickness of the In_{0.1}Ga_{0.9}As layers are equal to or less than 50 nm, the In_{0.1}Ga_{0.9}As layers exhibit excellent surface morphology.

(Study of V/III Ratio Dependence of Etch Pit Density)

The relationship between the etch pit density of the surface 20a of the n-type III-V compound semiconductor layer 20 and III/V ratio (the molar ratio of the number of Group V atoms to the number of Group III atoms) in the raw material in the fabrication of the n-type III-V compound semiconductor layer 20 was studied. Specifically, the n-type III-V compound semiconductor layer 20 made of an In_{0.1}Ga_{0.9}As layer was studied. The raw material gas includes In and Ga as Group III element and As as Group V element in this layer.

A number of GaAs substrates were prepared and a Te-doped InGaAs layer was grown on each GaAs substrate by MOVPE method. Triethyl-gallium (TEGa), trimethyl-indium (TMIn), diethyl-tellurium (DETe) and arsine (AsH₃) were used as precursors. The growth temperature of the InGaAs layers was 450 degrees Celsius. The thickness of the InGaAs layers is 50 nm. The III-V ratios used in the growth were 5, 40 and 100. When the III-V ratio is, for example, 100, then the number of As atoms in the raw material gas is 100 times as many as the number of Ga and In atoms. The etch pit density of the surfaces of these InGaAs layers were measured by observing their surfaces. The etch pit density values were equal to or less than 200 cm¹³. By use of the range of the above values, the n-type III-V compound semiconductor layer 20 of InGaAs with an excellent surface morphology can be formed.

(Study of Indium Composition Dependence of Etch Pit Density and Electron Concentration)

The relationship between electron concentration and the surface etch pit density of the surface 20a and indium composition “X” of the n-type III-V compound semiconductor layer 20 was studied. Specifically, the n-type III-V compound semiconductor layer 20 made of an In_{X}Ga_{1-X}As layer was studied.

A number of GaAs substrates were prepared and a Te-doped In_{X}Ga_{1-X}As layer was grown on each GaAs substrate by MOVPE method. Triethyl-gallium (TEGa), trimethyl-indium (TMIn), diethyl-tellurium (DETe) and arsine (AsH₃) were used as precursors. The growth temperature of the In_{X}Ga_{1-X}As layers was 450 degrees Celsius. The indium compositions “X” are 0.05, 0.1, 0.2, 0.3, 0.4 and 0.5 were used in the In_{X}Ga_{1-X}As layers.

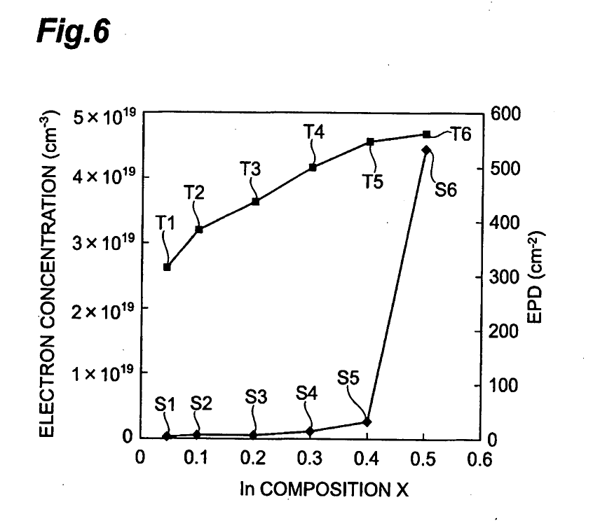

In this study, the thickness “d” of these In_{X}Ga_{1-X}As layers was 500 nm. The electron concentrations of the In_{X}Ga_{1-X}As layers were obtained by the Hole measurements of the In_{X}Ga_{1-X}As layers. In the study of the relationship between the indium composition and etch pit density, the In_{X}Ga_{1-X}As layers of thickness, 10 nm, were used. The etch pit density of the surfaces of these In_{X}Ga_{1-X}As layers were measured by observing their surfaces. These measurements are shown in FIG. 6.

FIG. 6 is a graph showing the relationship between the electron concentration and the etch pit density of a Te-doped In_{X}Ga_{1-X}As layer and the composition “X” of this In_{X}Ga_{1-X}As layer. The graph shows plots T1 to T6: Plot T1 corresponds to the electron concentration of the In_{0.05}Ga_{0.95}As layer; Plot T2 corresponds to the electron concentration of the In_{0.1}Ga_{0.9}As layer; Plot T3 corresponds to the electron concentration of the In_{0.2}Ga_{0.8}As layer; Plot T4 corresponds to the electron concentration of the In_{0.3}Ga_{0.7}As layer; Plot T5 corresponds to the electron concentration of the In_{0.4}Ga_{0.6}As layer; Plot T6 corresponds to the electron concentration of the In_{0.5}Ga_{0.5}As layer. This graph reveals that the electron concentrations are increased as the indium composition “X” is increased.

The graph shows plots S1 to S6: Plot SI corresponds to the etch pit density of the In_{00.5}Ga_{0.95}As layer; Plot S2 corresponds to the electron concentration of the In_{0.1}Ga_{0.9}As layer; Plot S3 corresponds to the electron concentration of the In_{0.2}Ga_{0.8}As layer; Plot S4 corresponds to the electron concentration of the In_{0.3}Ga_{0.7}As layer; Plot S5 corresponds to the electron concentration of the In_{0.4}Ga_{0.6}As layer; Plot S6 corresponds to the electron concentration of the In_{0.5}Ga_{0.5}As layer. This graph reveals that the etch pit density of the In_{X}Ga_{1-X}As layer (X≦0.4) become smaller as compared to the etch pit density of the In_{X}Ga₁₋ₓAs layer (X>0.4). Therefore, the surface morphology of the In_{X}Ga_{1-X}As layer (X≦0.4) becomes smaller as compared to the In_{X}Ga_{1-X}As layer (X>0.4).

(Study of Tunnel Junction)

Layered products each having a tunnel junction were fabricated as follows. A number of p-type GaAs substrates were prepared and a p-type GaAs spacer layer (the thickness of 200 nm) was grown on each substrate. The hole concentration of the p-type GaAs spacer layer was 3×10¹⁸ cm⁻³. Subsequently, a p-type In_{0.1}Ga_{0.9}As layer (10 nm) doped with carbon was grown on the substrate. The hole concentration of the In_{0.1}Ga_{0.9}As layer was 1.1×10²⁰ cm⁻³. Next, an n-type In_{0.1}Ga_{0.9}As layer (10 nm) doped with Te was grown on the p-type In_{0.1}Ga_{0.9}As layer. The electron concentration of the n-type In_{0.3}Ga_{0.7}As layer was 3.6×10¹⁹ cm⁻³. In this way, a tunnel junction was formed by the p-type In_{0.1}Ga_{0.9}As layer and n-type In_{0.3}Ga_{0.7}As layer.

Further, a n-type GaAs spacer layer (200 nm) doped with Si was grown on the n-type In_{0.3}Ga_{0.7}As layer. The electron concentration of the n-type GaAs layer was 1.0×10¹⁸ cm⁻³. An n-type GaAs contact layer (100 nm) doped with tellurium was on the n-type GaAs spacer layer. The electron concentration of the n-type contact layer was 2.0×10¹⁹ cm⁻³.

Next, an electrode of Au/Zn/Au was evaporated on the backside of the GaAs substrate, and another electrode of Ti/Pt/Au was evaporated on the n-type GaAs contact layer. A mesa having the diameter of 30 micrometers was formed using wet etching to fabricate a laminated body having a tunnel junction.

The contact resistance of the laminated body as obtained above was measured. The contact resistance was 6.0×10⁻⁶ Ωcm².

Another laminated body was formed in the same steps as above except for using a Si-doped n-type In_{0.3}Ga_{0.7}As layer instead of the Te-doped n-type In_{0.3}Ga_{0.7}As layer. The contact resistance of this laminated body was 1.5×10⁻⁵ Ωcm².

### EXAMPLE 1

A DBR portion having 32 pairs of the layers of Si-doped n-type GaAs and Si-doped n-type In_{0.9}Ga_{0.1}As was grown on an n-type GaAs substrate. An active layer of a double quantum well structure made of In_{0.2}Ga_{0.8}As was grown on the DBR portion. A p-type GaAs spacer layer doped with carbon was grown on the active layer. A C-doped p-type InGaAs layer and Te-doped n-type InGaAs layer (10 nm) were sequentially grown on the p-type spacer layer. The p-type InGaAs layer and n-type InGaAs layer from a tunnel junction. The thickness of the Te-doped n-type InGaAs layer was 10 nanometers, and this thickness value was two third of the thickness of the corresponding InGaAs layer doped with Si. SIMS measurements of the Te-doped n-type InGaAs layer and C-doped p-type InGaAs layer showed that the carbon concentration and silicon concentration were greater than 1.5×10²⁰ cm⁻³ and that an abrupt junction was formed without any diffusion at the interface between the n-type InGaAs layer and the p-type InGaAs layer.

Next, resist was applied to the n-type GaAs substrate to form a photoresist mask having a diameter of 5 micrometers by photolithography. The n-type InGaAs layer was wet-etched to form a mesa. The mesa step was 10 nanometers. After cleaning the substrate, an n-type GaAs spacer layer was grown to bury the mesa-shaped n-type InGaAs layer, and an n-type GaAs contact layer was grown thereon. The n-type dopant of the n-type GaAs spacer layer was silicon, and the n-type dopant of the n-type contact layer was tellurium. Since the mesa step was as small as 10 nanometers, anomalous growth of the n-type GaAs spacer layer was not observed around the mesa. Therefore, the flatness of the n-type GaAs spacer layer was improved.

An electrode was formed on the n-type GaAs contact layer and another electrode was formed on the backside of the n-type GaAs substrate. The electrode formed on the n-type GaAs contact layer has an opening, and a DBR portion having a plural pairs of the layers of amorphous silicon and Al₂O₃ was formed on the n-type GaAs contact layer. Thereafter, a part of the DBR portion which was located on the electrode was removed by lift-off. After the above steps, a surface emitting laser of Example 1 was fabricated.

### EXAMPLE 2

A surface emitting laser of Example 2 was fabricated in the same steps as Example 1 except that another DBR portion having GaAs layers and Al_{0.8}Ga_{0.2}As layers was formed instead of the DBR portion having the plural pairs of the layers of amorphous silicon and A₂O₃.

### EXAMPLE 3

A surface emitting laser of Example 3 was fabricated in the same steps as Example 1 except that the n-type InGaAs layer was grown after exposing the p-type InGaAs layer for the tunnel junction to oxygen atmosphere. After the p-type InGaAs layer was grown in the reactor, it was taken out from the reactor, so that the p-type InGaAs layer was exposed to oxygen atmosphere. Impurity levels coming from oxygen were introduced into the tunnel junction. The resistance of the tunnel junction was 4.5×10⁻⁶ Ωcm².

### EXAMPLE 4

A surface emitting laser of Example 4 was fabricated in the same steps as Example 1 except that the n-type GaInNAsSb layer doped with Te was grown instead of the n-type InGaAs layer for the tunnel junction. The electron concentration of the n-type GaInNAsSb layer was 3.5×10¹⁹ cm⁻³.

### EXAMPLE 5

A surface emitting laser of Example 5 was fabricated in the same steps as Example 1 except that the p-type GaAs_{0.8}Sb_{0.2} layer was grown instead of the p-type InGaAs layer for the tunnel junction. The n-type InGaAs layer and the p-type GaAs_{0.8}Sb_{0.2} layer form a type II superlattice structure, and the resistance of the tunnel junction was 3.8×10⁻⁶ Ωcm².

### COMPARATIVE EXAMPLE 1

A surface emitting laser of Comparative Example 1 was fabricated in the same steps as Example 1 except that the n-type InGaAs layer for the tunnel junction was doped with silicon of the n-type dopant.

(Measurement Result)

Current versus optical output characteristics and current versus voltage characteristics of the surface emitting lasers of Embodiments 1 to 5 and Comparative Example 1 were measured.

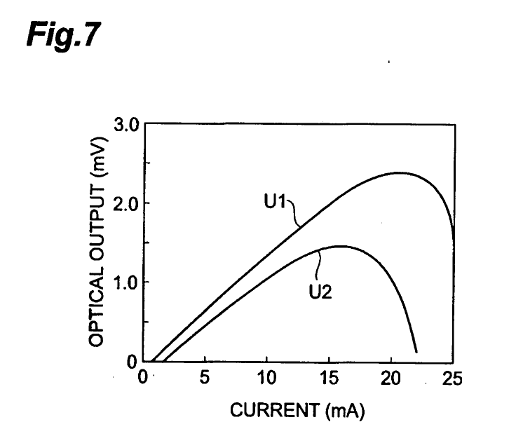

FIG. 7 is a graph showing current versus optical output characteristics of the surface emitting lasers of Embodiment 1 and Comparative Example 1. Solid line “U1” indicates the current versus optical output characteristics of the surface emitting laser of Embodiment 1. Solid line “U2” indicates the current versus optical output characteristics of the surface emitting laser of Comparative Example 1. The maximum optical output of the surface emitting laser of Embodiment 1 is 2.4 mW, whereas the maximum optical output of the surface emitting laser of Comparative Example 1 is 1.4 mW.

The maximum optical output of the surface emitting laser of Embodiment 2 is 2.3 mW. The maximum optical output of the surface emitting laser of Embodiment 3 is 2.5 mW. The maximum optical output of the surface emitting laser of Embodiment 4 is 2.4 mW. The maximum optical output of the surface emitting laser of Embodiment 5 is 2.7 mW.

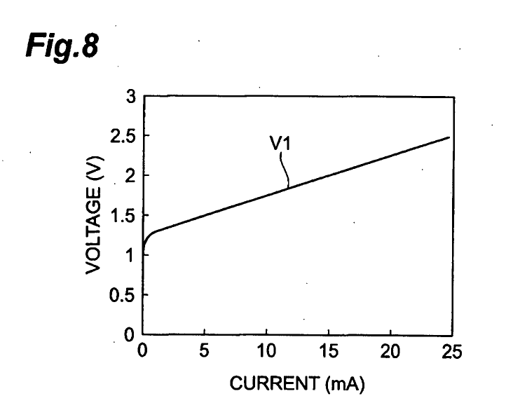

FIG. 8 is a graph showing current versus voltage characteristics of the surface emitting laser of Embodiment 1. Solid line “V1”indicates the current-voltage characteristics of the surface emitting laser of Embodiment 1. The differential resistance (dV/dI) of the surface emitting laser of Embodiment 1 was 50 ohm. On the other hand, the differential resistance of the surface emitting laser of Comparative Example 1 was 120 ohm.

The differential resistance of the surface emitting laser of Embodiment 2 was 50 ohm. The differential resistance of the surface emitting laser of Embodiment 3 was 40 ohm. The differential resistance of the surface emitting laser of Embodiment 5 was 25 ohm.

Furthermore, long-term stability of the surface emitting lasers of Embodiment 1 to 5 and Comparative Example 1 was studied. The current of 10 mA was fed to the surface emitting lasers of Embodiment 1 to 5 and Comparative Example 1 at the temperature of 85 degrees Celsius in a continuous fashion. After the application of the current for 3000 hours, the surface emitting lasers of Embodiment 1 to 5 did not exhibit the optical output variations, and this shows that the surface emitting lasers of Embodiment 1 to 5 have high reliability. This shows that secular variation of the tunnel junctions due to the dopant diffusion hardly occur in the surface emitting semiconductor device, such as surface emitting laser, operated in the high current application because the diffusion coefficient of tellurium is smaller than that of silicon.

Having described and illustrated the principle of the invention in a preferred embodiment thereof, it is appreciated by those having skill in the art that the invention can be modified in arrangement and detail without departing from such principles. We therefore claim all modifications and variations coming within the spirit and scope of the following claims.

What is claimed is:

1. A surface emitting semiconductor device comprising:
an active layer including a primary surface, the primary surface having first and second areas;
a p-type III-V compound semiconductor layer provided on the first and second areas of the primary surface of the active layer;
an n-type III-V compound semiconductor layer provided on the second area of the primary surface of the active layer, the n-type III-V compound semiconductor layer being provided on the p-type III-V compound semiconductor layer, the n-type III-V compound semiconductor layer and the p-type III-V compound semiconductor layer forming a tunnel junction, and the n-type III-V compound semiconductor layer containing tellurium as an n-type dopant; and
a burying layer made of III-V compound semiconductor, the n-type III-V compound semiconductor layer being buried by the burying layer.

2. The surface emitting semiconductor device according to claim 1, wherein the p-type III-V compound semiconductor layer contains carbon as a p-type dopant.

3. The surface emitting semiconductor device according to claim 1, wherein a thickness of the n-type III-V compound semiconductor layer is equal to or less than 50 nanometers.

4. The surface emitting semiconductor device according to claim 1, wherein the n-type III-V compound semiconductor layer includes In_{X}Ga_{1-X}As (0.05≦X≦0.4).

5. The surface emitting semiconductor device according to claim 1, wherein the n-type III-V compound semiconductor layer and p-type III-V compound semiconductor layer form a type II superlattice structure.

6. The surface emitting semiconductor device according to claim 5, wherein the n-type III-V compound semiconductor layer has a top and a side, and the burying layer covers the top and the side of the n-type III-V compound semiconductor layer.

7. The surface emitting semiconductor device according to claim 1, wherein the n-type III-V compound semiconductor layer and p-type III-V compound semiconductor layer form a type I superlattice structure.

8. The surface emitting semiconductor device according to claim 7, wherein the n-type III-V compound semiconductor layer has a top and a side, and the burying layer covers the top and the side of the n-type III-V compound semiconductor layer.

9. The surface emitting semiconductor device according to claim 1, wherein the p-type III-V compound semiconductor layer is made of InGaAs, and the n-type III-V compound semiconductor layer is made of one of the following: InGaAs; GaAsSb; GaInNAs; and GaInNAsSb.

10. The surface emitting semiconductor device according to claim 1, further comprising:
an n-type semiconductor substrate;
a first distributed Bragg reflector; and
a second distributed Bragg reflector,
wherein the p-type III-V compound semiconductor layer, the active layer and the n-type III-V compound semiconductor layer are provided between the first distributed Bragg reflector and the second distributed Bragg reflector, and the first and second distributed Bragg reflectors are mounted on the n-type semiconductor substrate.

11. The surface emitting semiconductor device according to claim 1, further comprising a contact layer provided on the burying layer and the contact layer is doped with an n-type dopant.

12. The surface emitting semiconductor device according to claim 11, wherein the burying layer is doped with an n-type dopant.

13. The surface emitting semiconductor device according to claim 12, wherein the n-type dopant in the burying layer is different form the n-type dopant in the contact layer.

14. The surface emitting semiconductor device according to claim 12, wherein the n-type dopant in the burying layer is Si and the n-type dopant in the contact layer is Te.

15. The surface emitting semiconductor device according to claim 1, further comprising:
a first distributed Bragg reflector; and
a second distributed Bragg reflector,
wherein the p-type III-V compound semiconductor layer, the active layer and the n-type III-V compound semiconductor layer are provided between the first distributed Bragg reflector and the second distributed Bragg reflector.

16. The surface emitting semiconductor device according to claim 1, further comprising:
a contact layer provided on the burying layer;
a first distributed Bragg reflector; and
a second distributed Bragg reflector provided on the contact layer,
wherein the p-type III-V compound semiconductor layer, the active layer, the n-type III-V compound semiconductor layer and the contact layer are provided between the first distributed Bragg reflector and the second distributed Bragg reflector.

17. The surface emitting semiconductor device according to claim 16, wherein the n-type III-V compound semiconductor layer has a mesa, and the first distributed Bragg reflector, the n-type III-V compound semiconductor layer, the active layer and the second distributed Bragg reflector are arranged on a predetermined axis.

18. The surface emitting semiconductor device according to claim 16, wherein the second distributed Bragg reflector includes first III-V compound semiconductor layers and second III-V compound semiconductor layers, and the first III-V compound semiconductor layers and second III-V compound semiconductor layers are arranged alternately.

19. The surface emitting semiconductor device according to claim 16, wherein the second distributed Bragg reflector includes first dielectric layers and second dielectric layers, and the dielectric layers and second dielectric layers are arranged alternately.

20. The surface emitting semiconductor device according to claim 1, wherein the surface emitting semiconductor device includes a surface emitting semiconductor laser.
